(19) United States
(12) Patent Application Publication
(10) Pub. No.: US 2023/0156967 A1
(43) Pub. Date: May 18, 2023

(54) CIRCUIT ASSEMBLY

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Koushi IGURA, Mie (JP); Hiroki SHIMODA, Mie (JP); Taiji YANAGIDA, Mie (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 17/923,060

(22) PCT Filed: May 18, 2021
(86) PCT No.: PCT/JP2021/018837

§ 371 Date: Nov. 3, 2022

(30) Foreign Application Priority Data
May 21, 2020 (JP) 2020-089136

(51) Int. Cl. H05K 7/20; H05K 5/04

(52) U.S. Cl. CPC H05K 7/2039; H05K 5/04

(57) ABSTRACT

Provided is a circuit assembly with a novel structure that can quickly reduce heat generation at a connection portion of a heat generating component. A circuit assembly includes a heat generating component that generates heat when energized; a energization member that connects to a connection portion of the heat generating component; a fastening member that fastens the energization member to the connection portion; and a heat capacity increasing component that thermally connects to a fastening site of the energization member and the connection portion and increases a heat capacity of the connection portion of the heat generating component.

### TECHNICAL FIELD

The present disclosure relates to a circuit assembly including a heat generating component.

### BACKGROUND ART

In a known circuit assembly provided with a heat generating component, such as a relay or fuse that generates heat when energized, a heat dissipating structure for dissipating the heat of the heat generating component may be provided. For example, in the structure described in Patent Document 1, heat generated by a relay housed in a case is dissipated using an intermediate portion of a bus bar that connects a connection portion of the relay and a connection terminal of a battery disposed outside the case. Specifically, a structure is described in which the intermediate portion of the bus bar, which extends outside the case housing the relay, is brought into contact with a chassis or a housing that houses an entire power supply apparatus via an insulative heat dissipation sheet, whereby heat generated by the relay is conducted to the chassis or the housing and dissipated.

### CITATION LIST

### Patent Documents

Patent Document 1: JP 2014-79093A

### SUMMARY OF INVENTION

### Technical Problem

In the structure of Patent Document 1, the heat dissipating structure is provided in the intermediate portion of the bus bar that forms an energization portion connecting the relay and the battery. Thus, though heat dissipation of the relay via the bus bar is promoted, there is a problem in that, when a large current flows, heat generated at the connection portion of the relay cannot be quickly reduced.

In view of this, a circuit assembly with a novel structure that can quickly reduce heat generation at a connection portion of a heat generating component is provided.

### Solution to Problem

A circuit assembly of the present disclosure includes a heat generating component that generates heat when energized; a energization member that connects to a connection portion of the heat generating component; a fastening member that fastens the energization member to the connection portion; and a heat capacity increasing component that thermally connects to a fastening site of the energization member and the connection portion and increases a heat capacity of the connection portion of the heat generating component.

### Advantageous Effects of Invention

According to the present disclosure, heat generation at a connection portion of a heat generating component can be quickly reduced.

### BRIEF DESCRIPTION OF DRAWINGS

FIG. 1 is a perspective view illustrating a circuit assembly according to a first embodiment.

FIG. 2 is an exploded perspective view illustrating the circuit assembly illustrated in FIG. 1 in a state with the lid member forming the case removed.

FIG. 3 is an exploded perspective view of the circuit assembly illustrated in FIG. 1.

FIG. 4 is a perspective view illustrating an energization member forming the circuit assembly illustrated in FIG. 1.

FIG. 5 is a cross-sectional view taken along V-V in FIG. 2.

FIG. 6 is a perspective view illustrating a circuit assembly according to a second embodiment and is an enlarged view of a main portion in a state with a lid member forming a case removed.

FIG. 7 is a cross-sectional view taken along VII-VII of FIG. 6.

FIG. 8 is a perspective view illustrating a circuit assembly according to a third embodiment and is an enlarged view of a main portion in a state with a lid member forming a case removed.

FIG. 9 is a cross-sectional view taken along IX-IX in FIG. 8.

FIG. 10 is a vertical cross-sectional view illustrating a circuit assembly according to a fourth embodiment and corresponds to FIG. 9.

### DESCRIPTION OF EMBODIMENTS

### Description of Embodiments of Present Disclosure

Firstly, embodiments of the present disclosure will be listed and described.

A circuit assembly of the present disclosure is

(1) a circuit assembly including a heat generating component that generates heat when energized; a energization member that connects to a connection portion of the heat generating component; a fastening member that fastens the energization member to the connection portion; and a heat capacity increasing component that thermally connects to a fastening site of the energization member and the connection portion and increases a heat capacity of the connection portion of the heat generating component.

According to the circuit assembly of the present disclosure, the heat capacity increasing component that increases the heat capacity of the connection portion is provided at and thermally in contact with the fastening site of the connection portion corresponding to the heat generating site of the heat generating component and the energization member connected to the connection portion. Thus, heat at the connection portion transferred to the fastening site of the connection portion of the heat generating component and the energization member can be reduced by suppressing an increase in the temperature via the heat capacity increasing component thermally in contact with the fastening site. As a result, compared to a known structure in which an energization member is brought into contact with another member at a site separated from the connection portion of the heat generating component and heat is dissipated, heat generated at the connection portion of the heat generating component can be quickly reduce by the heat capacity increasing component. Note that the heat generating component includes a component that generates heat when energized, such as a relay, fuse, or the like.

The heat capacity increasing component may be any kind of component as long as the heat capacity of the connection portion of the heat generating component can be increased by thermally coming into contact with the heat capacity increasing component to the fastening site of the connection portion and the energization member. For example, a component made of metal with high thermal conductivity, such as iron, copper, aluminum, an alloy thereof, or the like or a synthetic resin may be used. Also, the shape of the heat capacity increasing component is not particularly limited and may be any shape as long as the shape allows for the heat capacity increasing component to be in thermal contact with the fastening site of the connection portion and the energization member.

Any known fastening member may be used as the fastening member as long as it can be used to fasten the energization member, and advantageous examples include a bolt, a rivet, and the like.

(2) Preferably, a heat conducting member and a case are further provided, wherein the energization member is thermally in contact with the case via the heat conducting member. The heat transferred to the energization member can be dissipated from the case via the heat conducting member. Thus, the heat of the heat generating component can be reduced. In the present aspect, preferably, a sheet-like heat conducting member is used.

(3) Preferably, the heat capacity increasing component is made of metal; and the heat capacity increasing component is fastened to the connection portion together with the energization member via the fastening member. Because the heat capacity increasing component is made of metal and fastened to the connection portion together with the energization member, the heat capacity of the connection portion can be easily and reliably increased. Note that the heat capacity increasing component may be formed integrally with the energization member or may be a separate component from the energization member.

(4) Preferably, the heat capacity increasing component is overlapped with a surface on an opposite side to a contact surface of the energization member with the connection portion. Because the heat capacity increasing component is overlapped with the surface on the opposite side to the contact surface of the energization member with the connection portion, when the connection portion is fastened with the fastening member, the heat capacity increasing component is avoided from being disposed between the energization member and the connection portion. Thus, the heat capacity of the connection portion can be increased without increasing the electrical conduction resistance.

(5) Preferably, the heat capacity increasing component is formed of an end portion of the energization member and is folded back and overlapped with a surface on an opposite side to a contact surface of the energization member with the connection portion. Because the heat capacity increasing component is formed of the end portion of the energization member, an increase in the number of parts can be suppressed. Also, because the heat capacity increasing component is folded back and overlapped with the surface on the opposite side to the contact surface of the energization member with the connection portion, when the connection portion is fastened with the fastening member, the heat capacity increasing component is avoided from being disposed between the energization member and the connection portion. Thus, the heat capacity of the connection portion can be increased without increasing the electrical conduction resistance.

(6) Preferably, the energization member includes a holding portion that holds the end portion of the energization member forming the heat capacity increasing component and the surface on the opposite side of the contact surface of the energization member with the connection portion in an overlapped state. With the holding portion, the gap between the energization member and the heat capacity increasing component (folded-back end portion of the energization member) can be kept small, and the energization member and the heat capacity increasing component can be stably brought into contact with one another across a wide contact area. Accordingly, the heat capacity of the connection portion can be more reliably increased.

(7) Preferably, a coefficient of linear thermal expansion of the heat capacity increasing component ranges from ⅓ to 3 times a coefficient of linear thermal expansion of the fastening member. Because the heat capacity increasing component has a coefficient of linear thermal expansion similar to that of the fastening member, looseness of the fastening member caused by heat generation is unlikely to occur.

(8) Preferably, the heat capacity increasing component and the fastening member are a same material. Because the coefficient of linear thermal expansion of the heat capacity increasing component and the fastening member is equal, looseness of the fastening member caused by heat generation can be more reliably suppressed.

(9) Preferably, the heat capacity increasing component is formed of a cap for installing on the fastening member. Even with a cap for installing on the fastening member, the heat capacity of the connection portion can be increased, and heat generation at a connection portion of a heat generating component can be quickly reduced.

(10) Preferably, the cap is made of metal. By using the cap made of a metal with high thermal conductivity, an increase in the temperature at the connection portion can be suppressed.

(11) Preferably, a heat conducting member is provided between the cap and the fastening member. Using the heat conducting member, heat can be stably transferred from the fastening member to the cap. In the present aspect, preferably, a grease-like heat conducting member is used, for example.

(12) Preferably, the cap is made of synthetic resin. For example, by using a synthetic resin that is softer than metal as the material for the cap, the cap can be installed on the fastening member substantially without gaps. Thus, heat can be stably transferred from the fastening member to the cap, and the heat capacity of the connection portion can be more reliably increased.

### Details of Embodiments of Present Disclosure

Specific examples of the circuit assembly according to the present disclosure will be described below with reference to the drawings. Note that the present disclosure is not limited to these examples and is defined by the scope of the claims, and all modifications that are equivalent to or within the scope of the claims are included.

### First Embodiment

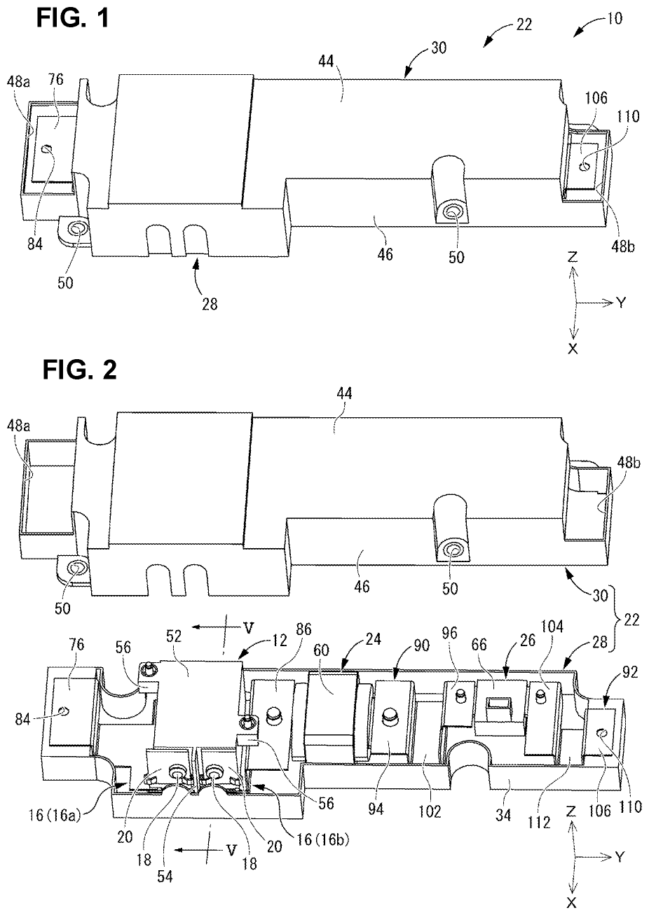

The first embodiment of the present disclosure will be described below with reference to FIGS. 1 to 5. A circuit assembly 10 of the first embodiment is installed in a vehicle (not illustrated), such as an electric vehicle or a hybrid vehicle, for example, and supplies and controls electric power from a power supply (not illustrated) such as a battery to a load (not illustrated) such as a motor. While the circuit assembly 10 can be oriented in any direction, in the following description, the X direction is defined as the forward direction, the Y direction is defined as the right direction, and the Z direction is defined as the upward direction. Also, for members including a plurality of members, a reference sign or number may only be given to one or more of the members of the plurality and not given to other members.

### Circuit Assembly 10

The circuit assembly 10 includes a relay 12, which is an example of a heat generating component that generates heat when energized; an energization bus bar 16, which is an example of an energization portion connecting to a connection portion 14 of the relay 12; and a bolt 18, which is an example of a fastening member that fastens the energization bus bar 16 to the connection portion 14 of the relay 12. Also, the circuit assembly 10 includes a heat capacity increasing component 20 that is thermally in contact with a fastening site A (a region surrounded by a two-dot dash line in the diagrams) of the energization bus bar 16 and the connection portion 14. The circuit assembly 10 further includes a case 22. The relay 12, the energization bus bar 16, the bolt 18, and the heat capacity increasing component 20 are all housed in the case 22. The case 22 also houses a fuse 24 that generates heat when energized and a current sensor 26.

### Case 22

The case 22 has an overall box-like shape and is made of a synthetic resin, for example. In the first embodiment, the case 22 is substantially rectangular, extending in the left-and-right direction in a plan view. The case 22 is divisible in the up-and-down direction and includes a base member 28 located on the lower side and a lid member 30 located on the upper side. The base member 28 has a box-like shape opening upward. The lid member 30 has a box-like shape opening downward. Also, the case 22 is formed by the upper opening portion of the base member 28 being covered by the lid member 30 and the base member 28 and the lid member 30 being fixed together. The method of fixing together the base member 28 and the lid member 30 is not limited, and various known fixing methods, such as adhesion, welding, press-fitting, protrusion-recess fitting, and the like can be used. Note that the case 22 may be made of metal, and the surface of the case 22 may be provided with an insulating cover to ensure it has insulating properties.

The base member 28 includes a bottom wall 32 with a substantially rectangular shape extending in the left-and-right direction and a peripheral wall 34 that projects upward from the outer peripheral edge portion of the bottom wall 32. In the first embodiment, a first housing recess portion 36 with a rectangular shape opening upward is formed in the upper surface of the bottom wall 32. In other words, a level difference 38 is formed on the upper surface of the bottom wall 32, and the portion surrounded by the level difference 38 corresponds to the first housing recess portion 36. In particular, in the first embodiment, at the upper surface of the bottom wall 32, four first housing recess portions 36 are formed with a predetermined size and at a predetermined separation distance in the left-and-right direction.

As illustrated in FIG. 5, a second housing recess portion 40 with a rectangular shape opening downward is formed at a position corresponding to the first housing recess portion 36 in the lower surface of the bottom wall 32. In other words, a level difference 42 is formed on the lower surface of the bottom wall 32, and the portion surrounded by the level difference 42 corresponds to the second housing recess portion 40. Four second housing recess portions 40 are provided with a size and positions corresponding to the first housing recess portions 36. Thus, in the first embodiment, at the positions where the first and second housing recess portions 36 and 40 are formed, the bottom wall 32 is thinner compared to other portions.

The lid member 30 includes an upper bottom wall 44 with a substantially rectangular shape extending in the left-and-right direction and a peripheral wall 46 that projects downward from the outer peripheral edge portion of the upper bottom wall 44. In the first embodiment, opening portions 48a and 48b with a rectangular shape are formed in the left and right end portions of the upper bottom wall 44 extending through in the up-and-down direction. Also, a plurality of bolt insertion holes 50 are formed in the outer peripheral portion of the lid member 30 extending through in the up-and-down direction.

### Relay 12, Fuse 24, and Current Sensor 26

The relay 12 includes a relay body 52 with a hollow rectangular parallelepiped-like shape. A pair of connection portions 14 and 14 (a first connection portion 14a and a second connection portion 14b) are provided on the front surface of the relay body 52 separated from one another in the left-and-right direction. An insulating plate 54 projecting frontward is provided between the first connection portion 14a and the second connection portion 14b.

Also a plurality of leg portions 56 projecting outward in the left-and-right direction are provided on the relay body 52. Bolt insertion holes are formed in the leg portions 56 extending through in the up-and-down direction.

The fuse 24 includes a fuse body 60 with a substantially rectangular parallelepiped-like shape. Connection portions 62 and 62 that are made of metal and project to both sides in the left-and-right direction are provided on the fuse body 60. Bolt insertion holes are formed in the connection portions 62 and 62 extending through in the up-and-down direction.

The current sensor 26 includes a sensor body 66 with a substantially rectangular parallelepiped-like shape. Connection portions 68 and 68 that are made of metal and project to both sides in the left-and-right direction are provided on the sensor body 66. Bolt insertion holes are formed in the connection portions 68 and 68 extending through in the up-and-down direction.

### Energization Bus Bar 16

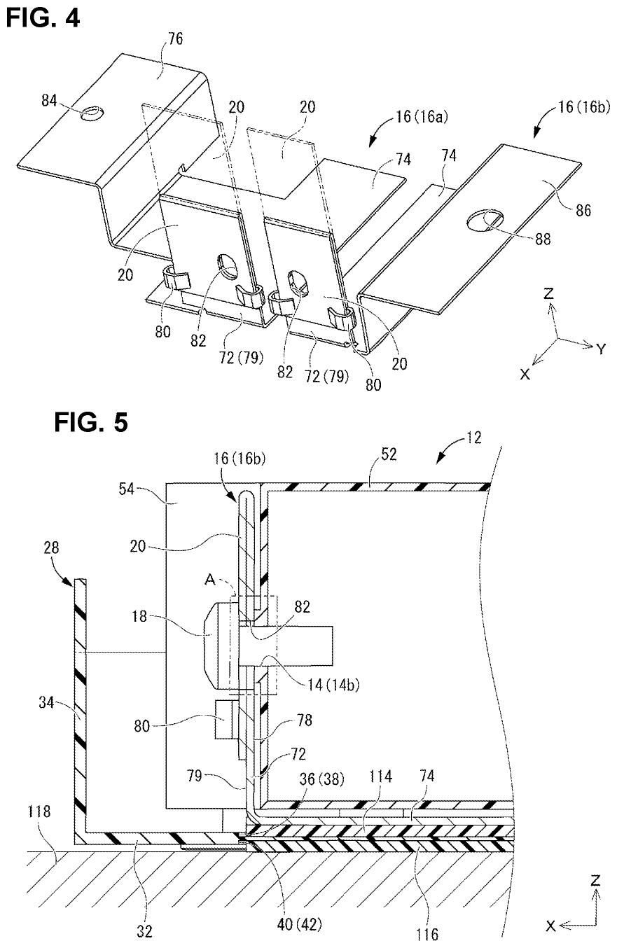

The energization bus bar 16 is formed by bending a metal plate material in a predetermined shape via a pressing process or the like. The material of the energization bus bar 16 is not limited, however copper, copper alloy, aluminum, aluminum alloy, or the like are preferably used. Note that the coefficient of linear thermal expansion of copper is approximately 16 to 17 (×10⁻⁶/K). Also, the coefficient of linear thermal expansion of aluminum is approximately 23 to 24 (×10⁻⁶/K). In the first embodiment, as also illustrated in FIG. 4, the pair of energization bus bars 16 and 16 (first energization bus bar 16a and second energization bus bar 16b) are provided separated from one another in the left-and-right direction.

The first energization bus bar 16a extends overall in the left-and-right direction. The first energization bus bar 16a includes, at the right end portion, a bolt fastening portion 72 with a rectangular shape extending in the up-and-down direction (YZ plane). A heat transfer portion 74 is a rectangular shape extending in the horizontal direction (XY plane) extends from the back of the lower end of the bolt fastening portion 72. Also, the first energization bus bar 16a includes, at the left end portion, an external connection portion 76 with a rectangular shape extending in the horizontal direction (XY plane). Also, the heat transfer portion 74 and the external connection portion 76 are connected by a portion bent like a crank in the intermediate portion in the left-and-right direction.

Furthermore, the upper end portion of the bolt fastening portion 72 of the first energization bus bar 16a is folded forward and overlaps the lower end portion of the bolt fastening portion 72. Note that the upper end portion of the bolt fastening portion 72 prior to being folded back is indicated by a two-dot dash line in FIG. 4. The folded back and overlapped portion corresponds to the heat capacity increasing component 20. In other words, in the first embodiment, the heat capacity increasing component 20 is made of metal and uses the same material as the energization bus bar 16 (first and second energization bus bars 16a and 16b). The first energization bus bar 16a is formed with double thickness at the position where the heat capacity increasing component 20 is formed. Also, the back surface of the bolt fastening portion 72 corresponds to a contact surface 78 that comes into contact with the first connection portion 14a of the relay 12. Thus, the upper end portion (heat capacity increasing component 20) of the bolt fastening portion 72 corresponding to the end portion of the first energization bus bar 16a is overlapped with a front surface 79 corresponding to the surface of the bolt fastening portion 72 on the opposite side to the contact surface 78.

Also, the first energization bus bar 16a is provided with a holding portion 80 that holds the heat capacity increasing component 20 and the front surface 79 of the bolt fastening portion 72 in an overlapped state. The shape of the holding portion 80 is not limited, however in the first embodiment, the holding portion 80 is a metal member formed integrally with the first energization bus bar 16a. Specifically, a pair of band-like holding portions 80 and 80 are provided on the left and right sides of the bolt fastening portion 72. Also, by bending and crimping the holding portions 80 and 80 with the heat capacity increasing component 20 (upper end portion of the bolt fastening portion 72) overlapped with the front surface 79 of the bolt fastening portion 72, the overlapped state of the heat capacity increasing component 20 (upper end portion of the bolt fastening portion 72) can be held.

Also, a bolt insertion hole 82 is formed in the bolt fastening portion 72 extending through in the front-and-back direction. In the first embodiment, the bolt insertion hole 82 is formed in the portion where the heat capacity increasing component 20 is provided (the portion where the upper end portion of the bolt fastening portion 72 is folded back and overlapped). Thus, the bolt insertion hole 82 is formed in the portion where the first energization bus bar 16a has double thickness extending through in the front-and-back direction. Note that the bolt insertion hole 82 may be formed by forming a through hole in both the upper end portion and the lower end portion of the bolt fastening portion 72 prior to folding back the upper end portion of the bolt fastening portion 72, folding back the upper end portion of the bolt fastening portion 72, and connecting the through holes. Alternatively, the bolt insertion hole 82 may be formed at the portion of double thickness after the upper end portion of the bolt fastening portion 72 is folded back and overlapped. By inserting the bolt 18 into the bolt insertion hole 82 and fastening it to the first connection portion 14a, the first energization bus bar 16a provided with the heat capacity increasing component 20 is affixed. In other words, by fastening the bolt 18, not only is the first energization bus bar with single thickness fixed to the first connection portion 14a, but the heat capacity increasing component 20 also with single thickness is also fixed.

Also, in the first embodiment, the bolt insertion hole 82 has an elliptical shape elongated in the up-and-down direction. Thus, when the relay 12 and the first energization bus bar 16a are fastened together as described below, the position in the up-and-down direction of the first energization bus bar 16a relative to the relay 12 can be adjusted. As a result, as described below, the heat transfer portion 74 can be more reliably thermally brought into contact with the case 22 (or a heat conduction sheet 114 described below). Also, a bolt insertion hole 84 is formed in the external connection portion 76 extending through in the thickness direction (up-and-down direction).

The second energization bus bar 16b has a substantially symmetrical shape in the left-and-right direction to the first energization bus bar 16a. That is, the bolt fastening portion 72 is provided at the front of the left end portion of the second energization bus bar 16b. The heat transfer portion 74 extends backward from the lower end portion of the bolt fastening portion 72. Also, a fuse connection portion 86 with a rectangular shape extending in the horizontal direction (XY plane) is provided on the right end portion of the second energization bus bar 16b. The heat transfer portion 74 and the fuse connection portion 86 are connected by a portion bent like a crank in the intermediate portion in the left-and-right direction. Also, a bolt insertion hole 88 is formed in the fuse connection portion 86 extending through in the thickness direction (up-and-down direction).

Furthermore, the upper end portion of the bolt fastening portion 72 of the second energization bus bar 16b is folded forward, forming the heat capacity increasing component 20. Also, the state of the heat capacity increasing component 20 (upper end portion of the bolt fastening portion 72) being folded and overlapped with the front surface 79 is held by the holding portions 80 and 80. Also, in a state in which the heat capacity increasing component 20 is provided, the bolt insertion hole 82 is formed in the bolt fastening portion 72 extending through in the thickness direction (front-and-back direction). By inserting the bolt 18 into the bolt insertion hole 82 and fastening it to the second connection portion 14b, the second energization bus bar 16b provided with the heat capacity increasing component 20 is affixed. In other words, by fastening the bolt 18, the heat capacity increasing component 20 together with the second energization bus bar 16b is fixed to the second connection portion 14b.

### Third Energization Bus Bar 90 and Fourth Energization Bus Bar 92

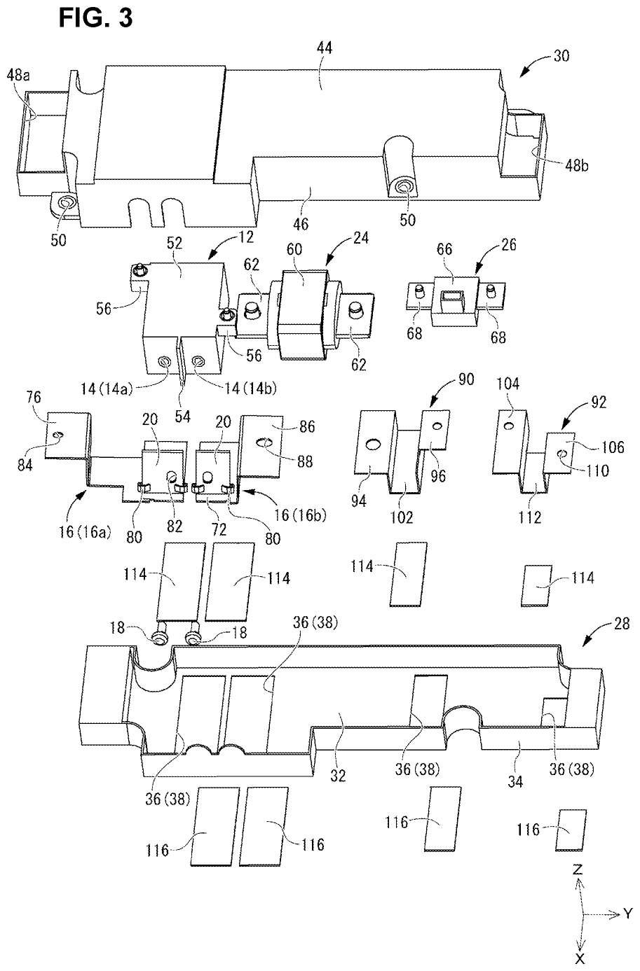

As illustrated in FIGS. 2 and 3, a third energization bus bar 90 is connected to the fuse 24 and the current sensor 26. Also, at the current sensor 26, a fourth energization bus bar 92 is connected on the opposite side to the side where the third energization bus bar 90 is connected. The third and fourth energization bus bars 90 and 92 are also formed by bending a metal plate material in a predetermined shape via a pressing process or the like as with the first and second energization bus bars 16a and 16b.

The third energization bus bar 90 includes, on the left and right end portions, a fuse connection portion 94 and a sensor connection portion 96 with a rectangular shape extending in the horizontal direction. That is, on the left side of the third energization bus bar 90, the fuse connection portion 94 is provided, and on the right side, the sensor connection portion 96 is provided. A bolt insertion hole is formed in both the fuse connection portion 94 and the sensor connection portion 96 extending through in the thickness direction (up-and-down direction).

In the first embodiment, the third energization bus bar 90 includes a substantially trough-shaped portion extending in the front-and-back direction and opening upward. The fuse connection portion 94 and the sensor connection portion 96 extends outward in the left-and-right direction from the left and right end portions of the upper opening portion of the substantially trough-shaped portion. Also, the bottom wall of the substantially trough-shaped portion corresponds to a heat transfer portion 102 thermally in contact with the case 22 (base member 28) when the circuit assembly 10 is assembled.

The fourth energization bus bar 92 has a structure similar to that of the third energization bus bar 90. In other words, the fourth energization bus bar 92 includes a substantially trough-shaped portion extending in the front-and-back direction and opening upward. A sensor connection portion 104 extends to the left from the left end portion of the upper opening portion of the substantially trough-shaped portion, and an external connection portion 106 extends to the right from the right end portion. A bolt insertion hole is formed in the sensor connection portion 104 extending through in the thickness direction (up-and-down direction). Also, a bolt insertion hole 110 is formed in the external connection portion 106 extending through in the thickness direction (up-and-down direction). Also, the bottom wall of the substantially trough-shaped portion corresponds to a heat transfer portion 112 thermally in contact with the case 22 (base member 28) when the circuit assembly 10 is assembled.

### Bolt 18

The relay 12 and the first and second energization bus bars 16a and 16b are fixed together via the bolts 18 and 18. Specifically, the first and second connection portions 14a and 14b and the bolt insertion holes 82 and 82 of the bolt fastening portions 72 and 72 are aligned in position, and the bolts 18 and 18 are inserted and fastened. A known material, such as iron or stainless steel, may be used as the material of the bolt 18. In the first embodiment, the bolt 18 is made of iron. Note that the coefficient of linear thermal expansion of iron is approximately 11 to 12 (×10⁻⁶/K).

### Heat Conduction Sheets 114 and 116

When the circuit assembly 10 is assembled, the heat transfer portions 74, 74, 102, and 112 of the first to fourth energization bus bars 16a, 16b, 90, and 92 are thermally in contact with the case 22 (base member 28). In the first embodiment, the heat conduction sheets 114, i.e., heat conducting members, are housed in the first housing recess portions 36 of the base member 28. Also, the heat transfer portions 74, 74, 102, and 112 are thermally in contact with the base member 28 via the heat conduction sheets 114.

Also, in the first embodiment, heat conduction sheets 116 are housed in the second housing recess portions 40 of the base member 28. When the circuit assembly 10 is installed in a vehicle, the base member 28 is thermally in contact with a heat dissipating body 118, such as a vehicle body panel or housing, via the heat conduction sheets 116.

The heat conduction sheets 114 and 116 have a sheet-like shape flat in the up-and-down direction are made of a synthetic resin with a larger thermal conductivity than air. Specifically, a silicone-based resin, a non-silicone-based acrylic resin, a ceramic-based resin, or the like can be used. A more specific example is heat-conductive silicone rubber. The heat conduction sheets 114 and 116 have flexibility and elasticity and can elastically deform, changing in the thickness dimension, in response to a force applied in the up-and-down direction. Note that in the first embodiment, the heat conduction sheets 114 and 116 are used as heat conducting members provided on the upper and lower surfaces of the base member 28. However, the heat conducting members are in no way limited to this configuration. The heat conducting members may have a discretionary shape, and a heat dissipating gap filler or heat conducting grease made of a silicone-based resin may be used, for example.

In particular, in the first embodiment, because the heat conduction sheets 114 are housed in the first housing recess portions 36 with the level difference 38, the heat conduction sheets 114 are positioned relative to the base member 28. Also, because the heat conduction sheets 116 are housed in the second housing recess portions 40 with the level difference 42, the heat conduction sheets 116 are positioned relative to the base member 28. Furthermore, the heat conduction sheets 114 are preferably sandwiched between the heat transfer portions 74, 74, 102, and 112 and the base member 28 in a compressed state in the up-and-down direction. By compressing the heat conduction sheets 114, the heat transfer portions 74, 74, 102, and 112 and the base member 28 can be brought into contact with a high degree of adhesion. Accordingly, the heat conduction sheets 114 can efficiently transfer heat from the heat transfer portions 74, 74, 102, and 112 to the base member 28. In a similar manner, the heat conduction sheets 116 are preferably sandwiched between the base member 28 and the heat dissipating body 118 in a compressed state in the up-and-down direction. By compressing the heat conduction sheets 116, the base member 28 and the heat dissipating body 118 can be brought into contact with a high degree of adhesion. Accordingly, the heat conduction sheets 116 can efficiently transfer heat from the base member 28 to the heat dissipating body 118.

### Assembly Process of Circuit Assembly 10

Next, a detailed example of the assembly process of the circuit assembly 10 will be described. Note that the assembly process of the circuit assembly 10 is not limited to that described below.

First, the lid member 30, the relay 12, the fuse 24, the current sensor 26, the first to fourth energization bus bars 16a, 16b, 90, and 92, and the bolts 18 are prepared. Then, the relay 12 is placed against the upper bottom wall 44 of the lid member 30 inverted upside down and the bolts are inserted in the leg portions 56 and fastened in the not-illustrated bolt fixing portions provided in the lid member 30. This fixes the lid member 30 and the relay 12 together. Then, the first and second energization bus bars 16a and 16b are placed above the relay 12, and the first and second connection portions 14a and 14b of the relay 12 and the bolt insertion holes 82 and 82 of the first and second energization bus bars 16a and 16b are aligned in position. Then, the bolts 18 and 18 are inserted in the first and second connection portions 14a and 14b and the bolt insertion holes 82 and 82 to fasten them together. In this manner, the relay 12 and the first and second energization bus bars 16a and 16b are fixed together.

Next, the third energization bus bar 90 and the fourth energization bus bar 92 are placed against the upper bottom wall 44 of the lid member 30, and the fuse 24 and the current sensor 26 are also placed from above. In this manner, the fuse connection portion 86 of the second energization bus bar 16b and the connection portion 62 on the left side of the fuse 24 are aligned and overlapped. Also, the connection portion 62 on the right side of the fuse 24 and the fuse connection portion 94 of the third energization bus bar 90 are aligned and overlapped. The sensor connection portion 96 of the third energization bus bar 90 and the connection portion 68 on the left side of the current sensor 26 are aligned and overlapped. Also, the connection portion 68 on the right side of the current sensor 26 and the sensor connection portion 104 of the fourth energization bus bar 92 are aligned and overlapped. Then, the bolts are inserted in the overlapped connection portions 62 and 68, the fuse connection portions 86 and 94, and the sensor connection portions 96 and 104 and fastened to not-illustrated bolt fixing portions provided on the lid member 30. In this manner, in addition to the relay 12 and the first and second energization bus bars 16a and 16b, the fuse 24, the current sensor 26, the third energization bus bar 90, and the fourth energization bus bar 92 are fixed to the lid member 30.

The base member 28 and the heat conduction sheets 114 and 116 are also prepared. Then, the heat conduction sheets 114 are housed in the first housing recess portions 36 of the base member 28 and fixed via adhesive or the like. The heat conduction sheets 116 are also housed in the second housing recess portions 40 and fixed via adhesive or the like. Then, the upper opening portion of the lid member 30 to which the relay 12, the fuse 24, the current sensor 26, and the first to fourth energization bus bars 16a, 16b, 90, and 92 are fixed is covered with the base member 28 to which the heat conduction sheets 114 and 116 are fixed, and the lid member 30 and the base member 28 are fixed together to form the case 22. Then, by inverting it, the circuit assembly 10 is completed.

Note that the order of fixing the relay 12, the fuse 24, the current sensor 26, and the first to fourth energization bus bars 16a, 16b, 90, and 92 to the lid member 30 is not limited to that described in the process described above. Also, the heat conduction sheets 114 provided between the first to fourth energization bus bars 16a, 16b, 90, and 92 (heat transfer portions 74, 74, 102, and 112) and the base member 28 may be fixed to the lower surface of the heat transfer portions 74, 74, 102, and 112 and not fixed to the base member 28. In a similar manner, the heat conduction sheets 116 provided on the lower surface of the base member 28 may be fixed to the heat dissipating body 118 and not fixed to the base member 28.

In the circuit assembly 10 assembled in this manner, the external connection portions 76 and 106 of the first energization bus bar 16a and the fourth energization bus bar 92 are exposed to the outside via the opening portions 48a and 48b of the lid member 30. Then, in a state where terminal portions provided on terminals of not-illustrated external electrical wires and the bolt insertion holes 84 and 110 of the external connection portions 76 and 106 are aligned in position and not-illustrated bolts are inserted and fastened, the external electrical wire and the first energization bus bar 16a and the fourth energization bus bar 92 are electrically connected. Also, by overlapping the circuit assembly 10 and the heat dissipating body 118 and inserting and fastening not-illustrated bolts in the bolt insertion holes 50 provided in the outer peripheral portion of the case 22 (lid member 30), the circuit assembly 10 is fixed to the heat dissipating body 118. In this manner, in the first embodiment, the heat conduction sheets 116 are compressed between the circuit assembly 10 and the heat dissipating body 118 in the up-and-down direction.

The circuit assembly 10 of the first embodiment is provided with the heat capacity increasing components 20 and 20 that are thermally in contact with the fastening sites A of the first and second connection portions 14a and 14b of the relay 12 at the first and second energization bus bars 16a and 16b. Specifically, by folding back and overlapping the upper end portion of the bolt fastening portions 72 and 72 of the first and second energization bus bars 16a and 16b, the heat capacity increasing component 20 is formed. Accordingly, at the fastening sites A of the first and second energization bus bars 16a and 16b and the first and second connection portions 14a and 14b of the relay 12, the first and second energization bus bars 16a and 16b have double thickness. Thus, compared to a case in which the first and second energization bus bars have simply single thickness, the heat capacity of the first and second energization bus bars 16a and 16b can be increased. In this manner, an increase in the temperature of the first and second energization bus bars 16a and 16b and thus the first and second connection portions 14a and 14b that connect to the first and second energization bus bars 16a and 16b can be suppressed, and the problem of heat generation when a large current temporarily flows can be solved.

Also, in the first embodiment, the heat transfer portions 74, 74, 102, and 112 of the first to fourth energization bus bars 16a, 16b, 90, and 92 are each thermally in contact with the case 22 (base member 28). Thus, the heat generated at the relay 12, the fuse 24, and the current sensor 26 when energized can be dissipated via the case 22. Accordingly, the problem of heat generated by the relay 12, the fuse 24, and the current sensor 26 can be solved. In particular, in the first embodiment, the heat conduction sheets 114 are provided between the heat transfer portions 74, 74, 102, and 112 and the base member 28. Thus, a stable transfer of heat from the heat transfer portions 74, 74, 102, and 112 to the base member 28 can be achieved. Furthermore, the heat conduction sheets 116 are provided on the lower surface of the base member 28. Thus, the base member 28 and the heat dissipating body 118 are thermally in contact with each other via the heat conduction sheets 116. Accordingly, the heat generated at the relay 12, the fuse 24, and the current sensor 26 is dissipated also from the heat dissipating body 118, allowing the heat dissipation effect to be improved.

Also, in the first embodiment, the heat capacity increasing components 20 and 20 are formed by the upper end portions of the bolt fastening portions 72 and 72 of the first and second energization bus bars 16a and 16b, and the bolt insertion holes 82 and 82 are formed on the portions where the heat capacity increasing components 20 and 20 are provided. Accordingly, by fastening the bolts 18 and 18, the heat capacity increasing components 20 and 20 are fixed together with the first and second energization bus bars 16a and 16b. In other words, in the first embodiment, the first and second energization bus bars 16a and 16b and the heat capacity increasing components 20 and 20 are integrally formed. This allows an increase in the number of parts to be avoided. Also, compared to a case in which the heat capacity increasing component is a separate member from the first and second energization bus bars 16a and 16b, the ease of assembly can be improved.

In particular, in the first embodiment, the upper end portions of the bolt fastening portions 72 and 72 are folded outward (forward) and overlapped. Accordingly, compared to a case in which the upper end portions of the bolt fastening portions are folded inward, the electrical path from the first and second connection portions 14a and 14b to the external connection portion 76 and the fuse connection portion 86 can be shortened. This allows an increase to the electrical conduction resistance when energized to be avoided. Also, the thermal path from the first and second connection portions 14a and 14b to the heat transfer portions 74 and 74 can be shortened. Accordingly, the heat generated at the first and second connection portions 14a and 14b is quickly dissipated via the heat transfer portions 74 and 74.

Also, the first and second energization bus bars 16a and 16b are provided with the holding portions 80 and 80 that hold the heat capacity increasing components 20 and 20 (upper end portions of the bolt fastening portions 72 and 72) in an overlapped state. Thus, no gap is formed between heat capacity increasing components 20 and 20 and the bolt fastening portions 72 and 72, i.e., between the upper end portions and the lower end portions of the bolt fastening portions 72 and 72 overlapping one another, and the heat capacity at the position where the heat capacity increasing components 20 and 20 are provided can be stably increased.

Note that the coefficient of linear thermal expansion of the heat capacity increasing component 20 (first and second energization bus bars 16a and 16b) is preferably set within a range of from ⅓ to 3 times the coefficient of linear thermal expansion of the bolts 18 and 18. The coefficient of linear thermal expansion of the heat capacity increasing component 20 (first and second energization bus bars 16a and 16b) is more preferably set within a range of from ½ to 2 times the coefficient of linear thermal expansion of the bolts 18 and 18. The coefficient of linear thermal expansion of the heat capacity increasing component 20 (first and second energization bus bars 16a and 16b) is even more preferably set within a range of from ⅔ to 3/2 times the coefficient of linear thermal expansion of the bolts 18 and 18. The coefficient of linear thermal expansion of the heat capacity increasing component 20 (first and second energization bus bars 16a and 16b) is most preferably set to be equal to the coefficient of linear thermal expansion of the bolts 18 and 18. By setting the coefficient of linear thermal expansion of the heat capacity increasing component 20 (first and second energization bus bars 16a and 16b) to from ⅓ to 3 times, i.e., relatively close to, the coefficient of linear thermal expansion of the bolts 18 and 18, looseness of the bolts 18 and 18 when heat is generated at the relay 12 can be suppressed. Note that, for example, in a case in which the first and second energization bus bars 16a and 16b are made of copper and the bolts 18 and 18 are made of iron, the coefficient of linear thermal expansion of the heat capacity increasing components 20 and 20 is approximately 1.4 times the coefficient of linear thermal expansion of the bolts 18 and 18.

In particular, because the coefficient of linear thermal expansion of the heat capacity increasing component 20 (first and second energization bus bars 16a and 16b) and the bolts 18 and 18 are equal, i.e., the heat capacity increasing component 20 (first and second energization bus bars 16a and 16b) and the bolts 18 and 18 are made of the same material, looseness of the bolts 18 and 18 when heat is generated at the relay 12 can be further suppressed.

### Second Embodiment

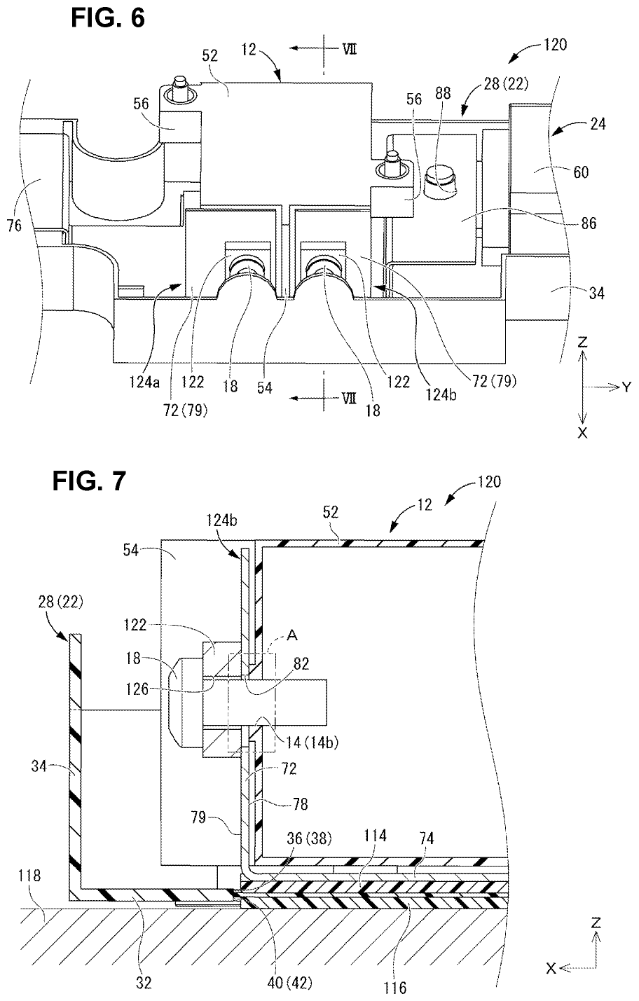

The second embodiment of the present disclosure will be described below with reference to FIGS. 6 and 7. A circuit assembly 120 of the second embodiment has basically a similar configuration to the circuit assembly 10 of the first embodiment but is different in that heat capacity increasing components 122 and 122 are separate members from first and second energization bus bars 124a and 124b, which are energization members. Hereinafter, the members and portions that are essentially the same as those in the embodiment described above are given the same reference sign as in the embodiment described above and a detailed description thereof will be omitted. Note that FIGS. 6 and 7 are diagrams illustrating the circuit assembly 120 in a state with the lid member 30 that forms the case 22 removed.

The heat capacity increasing component 122 according to the second embodiment has a rectangular block shape. A through hole 126 is formed in a substantially central portion of the heat capacity increasing component 122 extending through in the front-and-back direction. The material of the heat capacity increasing component 122 is not limited and can be any material that is capable of increasing the heat capacity of the first and second energization bus bars 124a and 124b and thus the first and second connection portions 14a and 14b when assembled. A metal with a high thermal conductivity is preferably used. Iron, copper, aluminum, an alloy thereof, or the like is more preferably used as the material of the heat capacity increasing component 122. In the second embodiment, the heat capacity increasing component 122 is made of metal. Note that the heat capacity increasing component 122 is preferably made of a metal with a lighter specific gravity than copper and iron. This is because a metal with a light specific gravity can reduce the effects of vibration in the bolt 18.

The heat capacity increasing components 122 of the second embodiment are fixed to the relay 12 together with the first and second energization bus bars 124a and 124b via the bolts 18. In other words, the first and second connection portions 14a and 14b of the relay 12, the bolt insertion holes 82 of the first and second energization bus bars 124a and 124b, and the through holes 126 of the heat capacity increasing components 122 are aligned in position with one another. Then, by inserting and fastening the bolts 18, the heat capacity increasing components 122 and 122 are fixed to the relay 12 together with the first and second energization bus bars 124a and 124b. Accordingly, the heat capacity increasing components 122 and 122 are thermally in contact with the fastening sites A of the first and second energization bus bars 124a and 124b and the first and second connection portions 14a and 14b. In particular, in the second embodiment also, the heat capacity increasing component 122 is overlapped with the front surface 79, which is the surface on the opposite side to the contact surface 78 with the first and second connection portions 14a and 14b at the bolt fastening portion 72 of the first and second energization bus bars 124a and 124b. Note that in the first embodiment, the upper end portion of the bolt fastening portion 72 is folded back, and the fastening site of the bolt 18 at the first and second energization bus bars 16a and 16b have double thickness. However, the fastening site of the bolt 18 on the first and second energization bus bars 124a and 124b of the second embodiment have single thickness.

In the circuit assembly 120 of the second embodiment also, because the heat capacity increasing component 122 is provided, the heat capacity at the fastening site A of the first and second connection portions 14a and 14b of the relay 12 and the first and second energization bus bars 124a and 124b is increased. Thus, heat generation at the relay 12 can be suppressed. Thus, a similar effect to that of the first embodiment is achieved.

In particular, in the circuit assembly 120 of the second embodiment, the heat capacity increasing component 122 is a separate member from the first and second energization bus bars 124a and 124b. Thus, for the material of the heat capacity increasing component 122, a material that tends to increase the heat capacity more than the first and second energization bus bars 124a and 124b can be used. Alternatively, for the material of the heat capacity increasing component 122, the same material (for example, iron) as the bolt 18 may be used, allowing looseness of the bolt 18 when heat is generated at the relay 12 to be reduced. The shape of the heat capacity increasing component 122 is not limited to a rectangular block shape, and a simple flat plate shape like a bus bar, a shape that tends to increase the heat capacity, or a shape capable of suppressing looseness of the bolt 18 when heat is generated may be used.

Also, in the second embodiment also, the heat capacity increasing component 122 is provided overlapping the front surface 79 of the bolt fastening portion 72 of the first and second energization bus bars 124a and 124b. Thus, the electrical path from the first and second connection portions 14a and 14b to the external connection portion 76 and the fuse connection portion 86 and the thermal path to the heat transfer portions 74 and 74 can be shortened, an increase in the electrical conduction resistance can be prevented, and heat can be quickly transferred.

### Third Embodiment

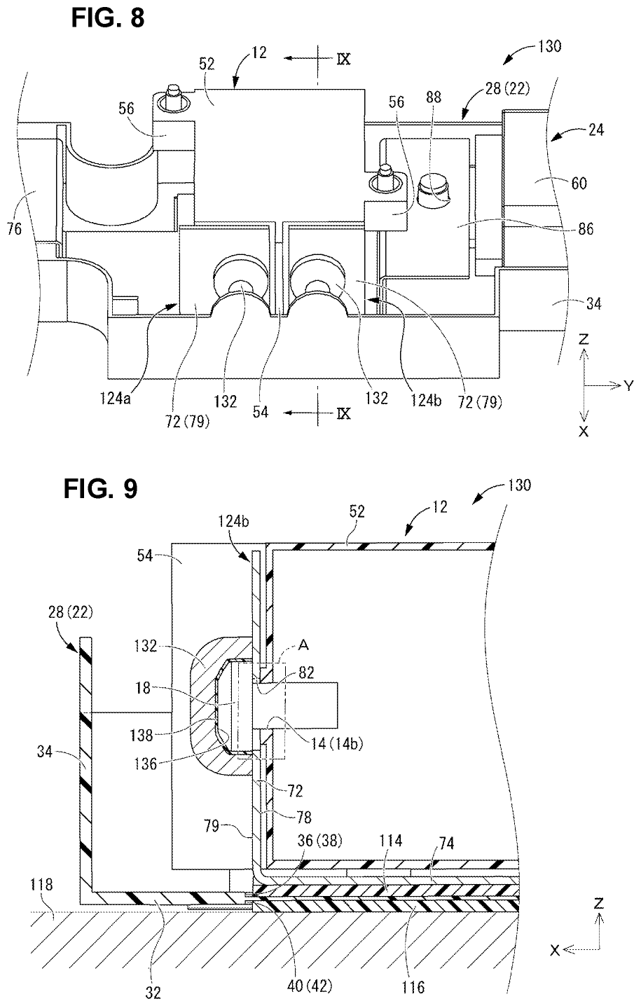

The third embodiment of the present disclosure will be described below with reference to FIGS. 8 and 9. A circuit assembly 130 of the third embodiment has basically a similar configuration to the circuit assembly 120 of the second embodiment but is different in that, instead of the heat capacity increasing component 122, caps 132 and 132 made of metal are installed on the bolts 18 as heat capacity increasing components. Note that in the third embodiment, the first and second energization bus bars 124a and 124b with a similar structure to that of the second embodiment are used. Also, FIGS. 8 and 9 are diagrams illustrating the circuit assembly 130 in a state with the lid member 30 that forms the case 22 removed.

That is, in the third embodiment, the heat capacity increasing component is formed by the cap 132 installed on the head portion of the bolt 18. Thus, a housing recess portion 136 that houses the head portion of the bolt 18 is formed in the cap 132. Accordingly, the cap 132 is thermally in contact with the fastening site A of the first and second energization bus bars 124a and 124b and the first and second connection portions 14a and 14b via the bolt 18. In the third embodiment, the cap 132 is made of a metal with a high thermal conductivity. The cap 132 is preferably made of iron, copper, aluminum, an alloy thereof, or the like, for example. That is, the heat capacity increasing component is not limited to a configuration in which it is fixed to a heat generating member (relay 12) together with an energization member (first and second energization bus bar) via a fastening member (bolt 18).

The caps 132 are installed on the head portions of the bolts 18 after the first and second energization bus bars 124a and 124b are fixed to the first and second connection portions 14a and 14b of the relay 12 via the bolts 18. Alternatively, the first and second energization bus bars 124a and 124b may be fixed to the first and second connection portions 14a and 14b of the relay 12 via the bolts 18 after the caps 132 are installed on the head portions of the bolts 18. A portion of the cap 132 on the outer peripheral side of the housing recess portion 136 may be in contact with the front surface 79 of the bolt fastening portion 72 of the first and second energization bus bars 124a and 124b or may not be in contact.

Note that preferably, a heat conducting grease 138, which is a heat conducting member, is provided between the inner surface of the housing recess portion 136 of the cap 132 and the head portion of the bolt 18. In this manner, even in a case in which a manufacturing error or the like causes a gap to be formed between the cap 132 and the bolt 18, heat can be stably transferred from the bolt 18 to the cap 132.

In the circuit assembly 130 of the third embodiment, the caps 132 that increase the heat capacity of the first and second connection portions 14a and 14b are provided on the bolts 18 that fix together the relay 12 and the first and second energization bus bars 124a and 124b. As a result, an increase in the temperature of the bolts 18 and thus the first and second connection portions 14a and 14b when heat is generated at the relay 12 can be suppressed by the caps 132.

In particular, in the third embodiment, because the caps 132 are made of metal, the heat capacity can be easily increased. Also, because the caps 132 are separate members from the first and second energization bus bars 124a and 124b and the bolts 18, for the material of the caps 132, a material that tends to increase the heat capacity more than the first and second energization bus bars 124a and 124b and the bolts 18 can be used. Note that by making the cap 132 and the bolt 18 have a similar coefficient of linear thermal expansion or by the cap 132 and the bolt 18 being the same material, a gap can be made unlikely to form between the cap 132 and the bolt 18 when heat is generated at the relay 12. Note that the cap 132 is preferably made of a metal with a lighter specific gravity than copper and iron. This is because a metal with a light specific gravity can reduce the effects of vibration in the bolt 18.

### Fourth Embodiment

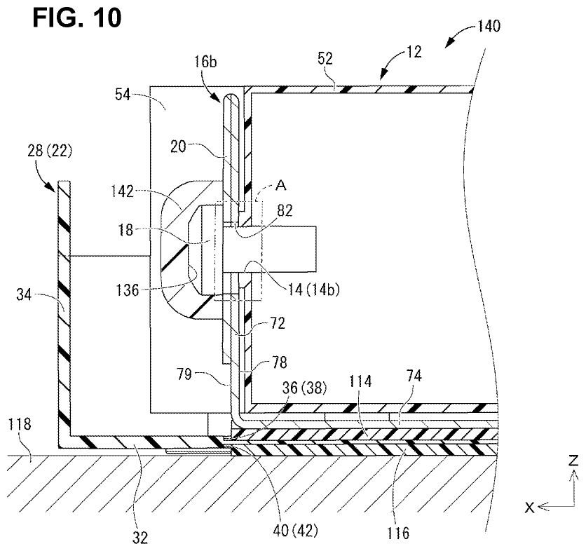

The fourth embodiment of the present disclosure will be described below with reference to FIG. 10. A circuit assembly 140 of the fourth embodiment has basically a similar configuration to the circuit assembly 10 of the first embodiment but is different in that a cap 142 made of synthetic resin is installed on the bolt 18 as a heat capacity increasing component. In other words, the cap 142 is thermally in contact with the fastening site A of the first and second energization bus bars 16a and 16b and the first and second connection portions 14a and 14b via the bolt 18. Note that FIG. 10 is a diagram illustrating the circuit assembly 140 in a state with the lid member 30 that forms the case 22 removed.

In the circuit assembly 140 of the fourth embodiment, the cap 142 that increases the heat capacity of the first and second connection portions 14a and 14b is provided on the bolt 18 that fixes together the relay 12 and the first and second energization bus bars 16a and 16b. Thus, an effect of suppressing an increase in the temperature from the cap 142 is added to that of the heat capacity increasing component 20 of the first embodiment. In particular, in the fourth embodiment, because synthetic resin which is relatively softer than metal is used for the cap 142, the head portion of the bolt 18 and the cap 142 can be brought into close contact substantially without gaps, allowing for the contact area between the cap 142 and the head portion of the bolt 18 to be substantially ensured. In this manner, heat can be stably transferred from the bolt 18 to the cap 142. Furthermore, because the cap 142 made of synthetic resin is used, electrical insulating properties at the head portion of the bolt 18 is ensured.

### Other Embodiments

The technology described in the present specification is not limited to the embodiments described above with reference to the drawings, and, for example, the following embodiments are also included in the technical scope of the technology described in the present specification.

(1) In the embodiments, the heat capacity increasing components 20 and 122 and the caps 132 and 142 are provided at the fastening site A of the first and second connection portions 14a and 14b of the relay 12, which is the heat generating component, and the first and second energization bus bars 16a, 124a, 16b, and 124b. However, no such limitation is intended. The heat capacity increasing component may be provided at a fastening site of the connection portion of the fuse or current sensor that generates heat when energized and the energization member (for example, the second to fourth energization bus bars in the embodiments). In other words, the heat generating component according to the present disclosure may be a fuse or a current sensor instead of or in addition to the relay. Note that the number of heat generating components provided is not necessarily a plurality and it is sufficient that one or more are provided.

(2) In the third embodiment, the cap 132 is used as the heat capacity increasing component instead of the heat capacity increasing component 20 of the first embodiment. However, the cap 132 may be used in addition to the heat capacity increasing components 20 and 122 of the first and second embodiments.

(3) The heat capacity increasing components 20 and 122 and the caps 132 and 142 of the embodiments, in a configuration other than that of the fourth embodiment, may be used in a combination of two or more. In other words, the heat capacity increasing component of the first and second embodiments combined may be used at the fastening site of the first and second connection portions of the relay and the first and second energization bus bars, for example. Alternatively, the heat capacity increasing component of the first and second embodiment may be used at the fastening site of the first and second connection portions of the relay and the first and second energization bus bars together with the heat capacity increasing component of the third and fourth embodiment at the fastening site of the connection portion of a fuse or current sensor and the energization member.

(4) In the embodiments, the heat capacity increasing components 20 and 122 and the caps 132 and 142 as heat capacity increasing components are provided at the fastening sites A of the first and second connection portions 14a and 14b of the relay 12 and the first and second energization bus bars 16a, 124a, 16b, and 124b. However, no such limitation is intended. It is sufficient that the heat capacity increasing component is provided at at least one fastening site of the connection portion and the energization member. Note that this also applies to a case in which the heat capacity increasing component is provided at the fastening site of the connection portion of a fuse or a current sensor and the energization member.

(5) A heat dissipation mechanism (for example, the heat transfer portions 74, 102, and 112, heat conduction sheets 114 and 116, and the like) for dissipating heat from the component (for example, the relay 12, the fuse 24, and the current sensor 26 in the embodiments) that generates heat when energized is not necessary. Even in a case in which the heat dissipation mechanism is provided, the structure is not limited to that described in the embodiments, and a known heat dissipation mechanism may be used. For example, a through hole may be provided in the case (the bottom wall of the base member, for example), and the heat transfer portion may be thermally in contact with the heat dissipating body directly or via the heat conducting member (the heat conduction sheet, for example).

(6) In the embodiments, the relay 12, the fuse 24, the current sensor 26, and the first to fourth energization bus bars 16a, 124a, 16b, 124b, 90, and 92 are all fixed to the lid member 30, but one or more may be fixed to the base member.

(7) In the embodiments, the bolt 18 is used as an example of the fastening member. However, the fastening member is not limited to the bolt, and a known fastening member such as a rivet capable of fastening together the energization member and the connection portion can be used.

(8) The heat capacity increasing component according to the present disclosure is not limited to the shape and material described in the embodiments, and the shape and material are not limited as long as that by providing the heat capacity increasing component, the heat capacity increases more than in the case of a single energization member.

### LIST OF REFERENCE NUMERALS

10 Circuit assembly (first embodiment)
12 Relay (heat generating component)
14 Connection portion
14a First connection portion
14b Second connection portion
16 Energization bus bar (energization member)
16a First energization bus bar
16b Second energization bus bar
18 Bolt (fastening member)
20 Heat capacity increasing component
22 Case
24 Fuse
26 Current sensor
28 Base member
30 Lid member
32 Bottom wall
34 Peripheral wall
36 First housing recess portion
38 Level difference
40 Second housing recess portion
42 Level difference
44 Upper bottom wall
46 Peripheral wall
48a, 48b Opening portion
50 Bolt insertion hole
52 Relay body
54 Insulating plate
56 Leg portion
60 Fuse body
62 Connection portion
66 Sensor body
68 Connection portion
72 Bolt fastening portion
74 Heat transfer portion
76 External connection portion
78 Contact surface
79 Front surface (surface on opposite side to contact surface)
80 Holding portion
82, 84 Bolt insertion hole
86 Fuse connection portion
88 Bolt insertion hole
90 Third energization bus bar
92 Fourth energization bus bar
94 Fuse connection portion
96 Sensor connection portion
102 Heat transfer portion
104 Sensor connection portion
106 External connection portion
110 Bolt insertion hole
112 Heat transfer portion
114 Heat conduction sheet (heat conducting member)
116 Heat conduction sheet
118 Heat dissipating body
120 Circuit assembly (second embodiment)
122 Heat capacity increasing component
124a First energization bus bar (energization member)
124b Second energization bus bar (energization member)
126 Through hole
130 Circuit assembly (third embodiment)
132 Cap (heat capacity increasing component)
136 Housing recess portion
138 Heat conducting grease (heat conducting member)
140 Circuit assembly (fourth embodiment)
142 Cap (heat capacity increasing component)
A Fastening site

1. A circuit assembly comprising:
a heat generating component that generates heat when energized;
an energization member that connects to a connection portion of the heat generating component;
a fastening member that fastens the energization member to the connection portion; and
a heat capacity increasing component that is thermally in contact with a fastening site of the energization member and the connection portion and increases a heat capacity of the connection portion of the heat generating component.

2. The circuit assembly according to claim 1, further comprising:
a heat conducting member and a case, wherein
the energization member is thermally in contact with the case via the heat conducting member.

3. The circuit assembly according to claim 1, wherein
the heat capacity increasing component is made of metal; and
the heat capacity increasing component is fastened to the connection portion together with the energization member via the fastening member.

4. The circuit assembly according to claim 3, wherein
the heat capacity increasing component is overlapped with a surface on an opposite side to a contact surface of the energization member with the connection portion.

5. The circuit assembly according to claim 3, wherein
the heat capacity increasing component is formed of an end portion of the energization member and is folded back and overlapped with a surface on an opposite side to a contact surface of the energization member with the connection portion.

6. The circuit assembly according to claim 5, wherein
the energization member includes a holding portion that holds the end portion of the energization member forming the heat capacity increasing component and the surface on the opposite side of the contact surface of the energization member with the connection portion in an overlapped state.

7. The circuit assembly according to claim 3, wherein
a coefficient of linear thermal expansion of the heat capacity increasing component ranges from ⅓ to 3 times a coefficient of linear thermal expansion of the fastening member.

8. The circuit assembly according to claim 3, wherein
the heat capacity increasing component and the fastening member are made of a same material.

9. The circuit assembly according to claim 1, wherein
the heat capacity increasing component is formed of a cap configured to be installed on the fastening member.

10. The circuit assembly according to claim 9, wherein
the cap is made of metal.

11. The circuit assembly according to claim 10, wherein
a heat conducting member is provided between the cap and the fastening member.

12. The circuit assembly according to claim 9, wherein
the cap is made of synthetic resin.
